(19) United States
(12) Patent Application Publication
(10) Pub. No.: US 2005/0120326 A1
(43) Pub. Date: Jun. 2, 2005

(54) Method for producing for a mask a mask layout which avoids aberrations

(75) Inventors: Armin Semmler, Munchen (DE); Jorg Thiele, Munchen (DE); Christian Meyne, Munchen (DE); Christof Bodendorf, Munchen (DE)

Correspondence Address: BEVER HOFFMAN & HARMS, LLP;TRI-VALLEY OFFICE, 1432 CONCANNON BLVD., BLDG. G, LIVERMORE, CA, 94550, US

(73) Assignee: Infineon Technolgies AG, Munchen (DE)

(21) Appl. No.: 10/997,695

(22) Filed: Nov. 24, 2004

(30) Foreign Application Priority Data
Nov. 27, 2003 (DE) 103 56 693.7

(51) Int. Cl. G06F 17/50; G03F 9/00

(52) U.S. Cl. 716/19; 716/21; 430/4; 430/5

(57) ABSTRACT

A method for producing for a mask a mask layout which avoids aberrations in which a provisional auxiliary mask layout produced, in particular in accordance with a prescribed electrical circuit diagram is converted into the mask layout with the aid of an OPC method. At least two different OPC variants are used in the course of the OPC method by subdividing the original auxiliary mask layout into at least two layout areas and processing each of the layout areas in accordance with one of the at least two OPC variants.

### FIELD OF THE INVENTION

The invention relates to photolithographic semiconductor fabrication, and more particularly to methods that use masks to transpose (image) circuit structure features onto a semiconductor wafer.

### BACKGROUND OF THE INVENTION

It is known that, in lithography methods, aberrations can occur if the structures to be imaged become very small and have a critical size or a critical distance with respect to one another. The critical size is generally referred to as the “CD” value (CD: Critical Dimension).

What is more, aberrations may occur if structures are arranged so closely next to one another that they influence one another reciprocally during imaging; these aberrations based on “proximity effects” can be reduced by modifying the mask layout beforehand with regard to the “proximity phenomena” that occur. Methods for modifying the mask layout with regard to avoiding proximity effects are referred to by experts by the term OPC methods (OPC: Optical Proximity Correction).

FIG. 1 illustrates a lithography process without OPC correction. The illustration reveals a mask 10 with a mask layout 20 that is intended to produce a desired photoresist structure 25 on a wafer 30. The mask layout 20 and the desired photoresist structure 25 are identical in the example in accordance with FIG. 1. A light beam 40 passes through the mask 10 and also a focusing lens 50 arranged downstream of it and falls onto the wafer 30, thereby imaging the mask layout 20 on the wafer 30 coated with photoresist. On account of proximity effects, aberrations occur in the region of closely adjacent mask structures with the consequence that the resulting photoresist structure 60 on the wafer 30 in part deviates considerably from the mask layout 20 and thus from the desired photoresist structure 25. The photoresist structure that results on the wafer 30, said photoresist structure being designated by the reference symbol 60, is illustrated in enlarged fashion and schematically beneath the wafer 30 for improved illustration in FIGS. 1 and 2.

In order to avoid or to reduce these aberrations, it is known to use OPC methods that modify the mask layout 20 beforehand in such a way that the resulting photoresist structure 60 on the wafer 30 corresponds to the greatest possible extent to the desired photoresist structure 25.

FIG. 2 shows a previously known OPC method described in the document “A little light magic” (Frank Schellenberg, IEEE Spectrum, September 2003, pages 34 to 39), in which the mask layout 20′ is altered compared with the original mask layout 20 in accordance with FIG. 1. The modified mask layout 20′ has structure alterations which are smaller than the optical resolution limit and therefore cannot be imaged “1:1”. These structure alterations nevertheless influence the imaging behavior of the mask, as can be discerned at the bottom of FIG. 2; this is because the resulting photoresist structure 60 corresponds distinctly better to the desired photoresist structure 25 than is the case with the mask in accordance with FIG. 1.

In the case of the previously known OPC methods by which a “final” mask layout (c.f. mask 20′ in accordance with FIG. 2) is formed from a provisional auxiliary mask layout (e.g. the mask layout 20 in accordance with FIG. 1), a distinction is made between so-called “rule-based” and “model-based” OPC methods.

In the case of rule-based OPC methods, the formation of the final mask layout is carried out using rules, in particular tables, defined beforehand. The method disclosed in the two US patents U.S. Pat. No. 5,821,014 and U.S. Pat. No. 5,242,770, by way of example, may be interpreted as a rule-based OPC method, in the case of which optically non-resolvable auxiliary structures are added to the mask layout according to predetermined fixed rules, in order to achieve a better adaptation of the resulting photoresist structure (reference symbol 60 in accordance with FIGS. 1 and 2) to the desired phbtoresist structure (reference symbol 25 in accordance with FIGS. 1 and 2). In the case of these methods, then, a mask optimization is carried out according to fixed rules.

In model-based OPC methods, a lithography simulation method is carried out, in the course of which the exposure operation is simulated. The simulated resulting photoresist structure is compared with the desired photoresist structure, and the mask layout is varied or modified iteratively until a “final” mask layout is present, which achieves an optimum correspondence between the simulated photoresist structure and the desired photoresist structure. The lithography simulation is carried out with the aid of a, for example, DP-based lithography simulator that is based on a simulation model for the lithography process. For this purpose, the simulation model is determined beforehand by “fitting” or adapting model parameters to experimental data. The model parameters may be determined for example by evaluation of so-called OPC curves for various CD values or structure types. One example of an OPC curve is shown in FIG. 2A and will be explained in connection with the associated description of the figures. Model-based OPC simulators or OPC simulation programs are commercially available. A description is given of model-based OPC methods for example in the article “Simulation-based proximity correction in high-volume DRAM production” (Werner Fischer, Ines Anke, Giorgio Schweeger, Jörg Thiele; Optical Microlithography VIII, Christopher J. Progler, Editor, Proceedings of SPIE VOL. 4000 (2000), pages 1002 to 1009) and in the German patent specification DE 101 33 127 C2.

Irrespective of whether a model-based or a rule-based OPC method is involved in an OPC method, OPC variants can also differ from one another with regard to their respective optimization aim. For example, so-called “target” OPC method and so-called process window OPC methods, for example “defocus” OPC methods, have different optimization aims:

The aim of target OPC methods is to hit as accurately as possible the prescribed target for the individual geometric dimensions of the mask structures in the case of correctly observing all the prescribed technological and methodological conditions (for example focus, exposure to light, etc.). Thus, in the case of a target OPC variant it is assumed that all prescribed process parameters are “hit” or set and observed in an ideal way. In this case the term “target” is understood to mean the structural size of the main structures to be imaged.

Since the gate length of transistors is of decisive importance for their electrical behavior, target OPC methods are used, in particular, for the gate level of masks. However, it is disadvantageous in the case of the target OPC variant that the prescribed geometric dimensions of the mask structures are actually observed only when the prescribed process parameters are observed in a quasi-exact fashion. If fluctuations arise in the process parameters, it is possible for sometimes considerable deviations to occur between the desired mask structures or mask dimensions and the actually resulting mask structures and mask dimensions; this can lead, for example, to breaking of lines or to a short circuit between lines. The resulting process window is therefore generally relatively small in the case of a target OPC method.

By contrast, process window OPC methods, for example defocus OPC methods, have the aim of rendering as large as possible the process window—that is to say the permissible parameter range of the process parameters for the exposure process with the resulting mask—in order to ensure the observation of the mask specifications even in the case of process fluctuations. It is accepted in this case in defocus OPC methods that the target geometric mask dimensions are not met exactly; deviations are therefore deliberately accepted in order to enlarge the process window and thus the tolerance range during later use of the mask.

A defocus OPC method is described, for example in the above named German patent DE 101 33 127. In this method, a “fictitious” defocus value is prescribed which forms a basis for simulating the exposure operation; this defocus value specifies that the resist structure to be exposed with the mask is situated somewhat outside the optimal focal plane. Despite the supposedly present defocusing, in the course of the OPC method an attempt is made to achieve an optimum imaging behavior of the mask; thus, an attempt is made to compensate the aberration caused by the supposed defocusing. The effect of this “compensation operation” is to change the form of the mask layout in such a way that both the line structures are formed more widely, and that a larger distance is produced between two adjacent line structures in each case. A mask is therefore obtained with the aid of which, given the use of a focused exposure, the probability of the formation of wider line structures, and the formation of larger distances between adjacent line structures in each case is higher than the probability of the formation of excessively small line structures and the formation of excessively small distances between adjacent line structures.

### SUMMARY OF THE INVENTION

The invention is directed to an improved method of the type specified in the introduction to the effect that aberrations, in particular as a result of proximity effects, are reduced even better than before.

Accordingly, it is provided according to the invention that in the course of the OPC method at least two different OPC variants are used subdividing the original auxiliary mask layout into at least two layout areas and processing each of the layout areas in accordance with one of the at least two OPC variants.

A substantial advantage of the method according to the invention consists in that each of the layout areas is optimized with an individually assigned OPC variant that is particularly suitable in each case for the respective layout area. According to the invention therefore, there is no “overall”, mask-embracing identical optimization for all layout areas of the layout, but instead an individual optimization referred to layout areas. The result of this mode of procedure is that after termination of the OPC method a final mask layout is present with which a particularly high process stability is achieved. The term “process stability” is understood here to mean that a sufficiently large process window is achieved, on the one hand, and that prescribed mask parameters or target parameters are achieved optimally, on the other hand.

A further substantial advantage of the method according to the invention consists in that fewer OPC process cycles or OPC passes are required overall until the optimum, final mask layout has been determined than is the case with the previously known “pure” target OPC and “pure” defocus OPC methods. A substantial process acceleration is thus additionally achieved because of the separation of the mask layout into at least two layout areas, and of the optimization of these layout areas for each of them individually.

A third substantial advantage of the method according to the invention consists in that there is generally no need for post-processing. Post-processing is understood here to mean that mask defects possibly present in the final mask layout are removed manually or with further optimization programs using DV systems. Specifically, because the optimization is in terms of individual layout areas there is in general no need in the method according to the invention for manual “reworking” of the mask layout, because mask defects occur only seldom enough to be negligible.

A fourth substantial advantage of the method according to the invention consists in that it is possible to appeal to already known and tried and tested OPC variants. It is necessary merely to carry out a subdivision of layout areas and to select the OPC variant particularly suitable in each case for the respective layout areas of the mask layout.

Since—as stated above—process window OPC methods, in particular defocus OPC methods, and target OPC methods have already been tested in practice, it is considered as advantageous within the course of developing the method if the method comprises at least one process window OPC variant, in particular a defocus OPC variant, and/or at least one target OPC variant.

As has already been explained at the beginning, gate structures of transistors, in particular, are especially critical, since with these structures it is particularly important to observe the prescribed geometric dimensions, in particular the gate length. It is therefore considered as advantageous within the course of a further improvement of the method according to the invention if the provisional auxiliary mask layout is subdivided into a layout area with active structures and into a layout area with inactive structures such that it is possible to go into the specific optimization requirements of the active structures, in particular.

It is preferred for the layout area with the active structures to be subjected to the target OPC variant, and for the layout area with the inactive structures to be subjected to the defocus OPC variant. In this case, the gate structures of transistors are preferably treated as the active structures.

The active layout areas can be determined particularly simply and therefore advantageously when the provisional auxiliary mask layout and the mask layout, describing the active areas and thus the gate structures, of masks prearranged in terms of layout are “laid over one another” by software or by hand, and those areas which are situated over active zones—for example diffusion zones —are treated as active structures. The masks which define the diffusion zones, for example, can be used for the “process of laying one over another”.

It is also considered advantageous when transition areas (“buffer zones”) are formed between the active and the inactive layout areas, and when these transition zones are optimized separately; the buffer zones can also be assigned to the target OPC variant, for example.

Both for the defocus OPC variant and for the target OPC variant, it is advantageously possible to select in each case either a model-based OPC variant or a rule-based OPC variant; however, model-based variants are to be preferred in each case.

It is also considered as advantageous when a modified auxiliary mask layout is firstly formed before carrying out the OPC method with the provisional auxiliary mask layout by supplementing the mask structures of the provisional auxiliary mask layout in a first modification step with the formation of modified mask structures in accordance with prescribed placing rules by means of optically non-resolvable auxiliary structures with the formation of the modified auxiliary mask layout, and the final mask layout is produced with the aid of the OPC method by using the modified auxiliary mask layout. Reference may be made to the U.S. Pat. Nos. 5,821,014 and 5,242,770 with reference to the mode of procedure when adding optically non-resolvable auxiliary structures.

It is also considered as advantageous when those layout areas which are provided with the optically non-resolvable auxiliary structures are subjected to a different OPC variant from the layout areas without the optically non-resolvable auxiliary structures. For example, the layout areas with the optically non-resolvable auxiliary structures can be subjected to a target OPC variant, and the surrounding layout areas are subjected to a defocus OPC variant.

Since the layout areas with the active structures are very critical, because the electrical behavior of the later electric components is generally a function of these structures, it is considered to be advantageous when firstly the layout areas with the active structures, in particular firstly the layout areas with the gate structures, are supplemented by means of optically non-resolvable auxiliary structures. Only when the active structures with the optically non-resolvable auxiliary structures are provided it is then also possible to optimize the remaining layout areas appropriately.

It is also considered to be advantageous when only the layout areas with the active structures, in particular only the layout areas with the gate structures, are supplemented by means of the optically resolvable auxiliary structures. To be precise, it is thereby excluded that optically non-resolvable auxiliary structures for inactive layout areas can impair adjacent active layout areas.

Moreover, it is preferably ensured when producing the final mask layout that wiring areas are not situated over active layout areas if no contact is to remain with the latter.

Moreover, when producing the final mask layout, pad structures (for example “landing pads”) and remaining wiring structures are preferably treated differently, since because of the subsequently required contacting steps pad structures are subject to different requirements than the remaining wire structures. It is preferred to use a target OPC variant when producing the mask layout for the pad structures.

It is also considered as advantageous when the method is carried out—in particular only—on non-gate levels, in particular on RX areas (=diffusion zones in the case of logic chips) and/or on metallization levels.

Moreover, CD critical and non-CD critical structures can advantageously be treated with different OPC variants.

The method can be used, for example, for DRAM mask layouts. It is then preferred in this case to process cell field structures and cell field edge structures with different OPC variants; this is because the cell field edge frequently consists of dummy structures which are not required functionally in electrical terms. Thus, electrically necessary mask structures and unnecessary dummy structures are preferably treated differently.

### BRIEF DESCRIPTION OF THE DRAWINGS

In order to elucidate the invention,

FIG. 1 is a perspective view depicting a lithography process without OPC correction;

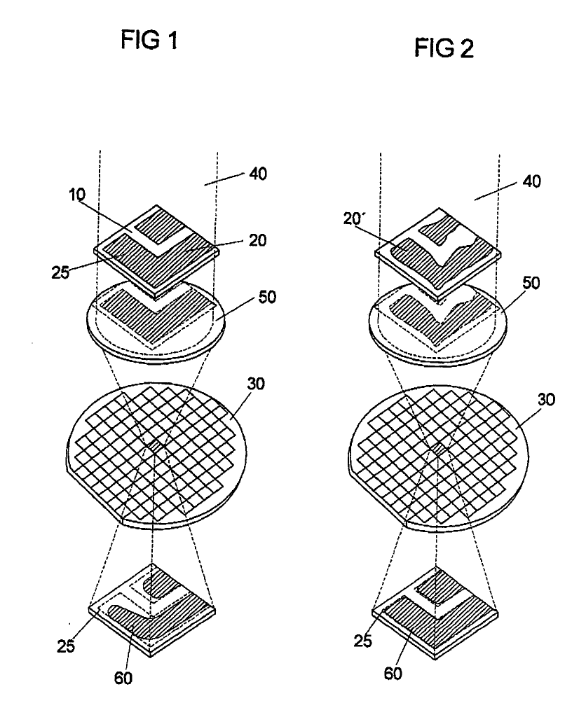

FIG. 2 is a perspective view depicting a lithography process with an OPC correction;

FIG. 2A shows an illustration of the dependence of the CD value on the distance between the mask structures among one another;

FIGS. 3A and 3B show examples of aberrations in a resulting photoresist structure because of a non-optimum mask layout which was produced with a model-based target OPC method according to the prior art;

FIGS. 4A and 4B show a further example of aberrations in the case of use of a model-based target OPC method according to the prior art;

FIG. 5 shows a provisional auxiliary mask layout which is processed in accordance with a first exemplary embodiment of the method according to the invention;

FIG. 6 shows a final mask layout formed from the provisional auxiliary mask layout in accordance with FIG. 5;

FIG. 7 shows a second exemplary embodiment of the method according to the invention, in which optically non-resolvable structures are firstly placed in active layout areas; and

FIGS. 8 and 9 show a third, fourth and fifth exemplary embodiment of the method according to the invention, in which the optically non-resolvable structures are placed exclusively in active layout areas, and contact hole charge areas (landing pads) and wiring structures over diffusion zones are treated separately.

### DESCRIPTION OF A PREFERRED EXEMPLARY EMBODIMENT

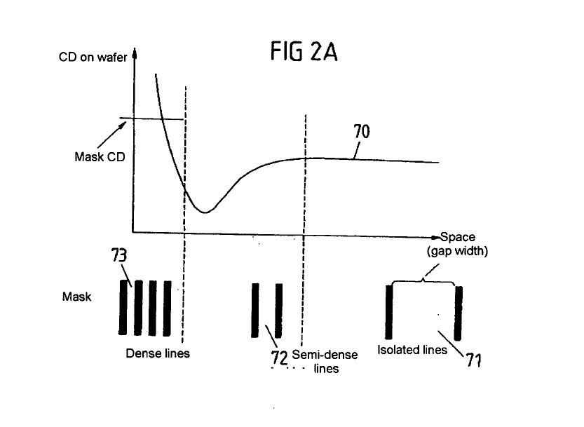

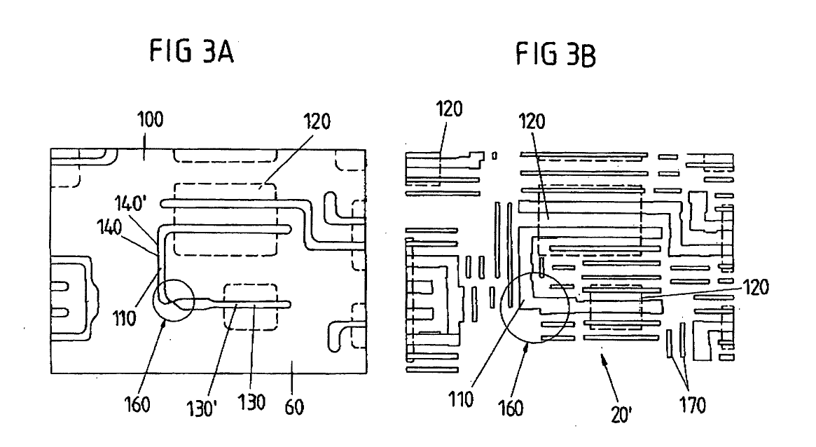

FIG. 2A illustrates an OPC curve 70 specifying how the CD values vary in a manner dependent on the distance between the main structures, for example thus in the case of lines. In the case of isolated lines 71, the CD value is largely independent of the distance between the structures. In the case of average, semi-dense main structures 72, the CD value falls in the direction of smaller structure distances before it rises significantly again in the case of very dense structures 73.

In this case, the OPC curve 70 describes the CD value profile on the wafer given a constant mask CD value, which is likewise depicted in FIG. 2A for comparison.

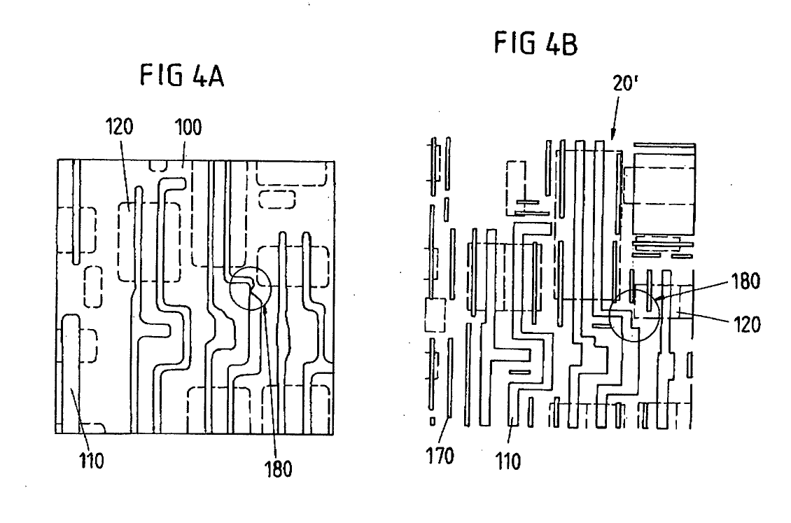

FIGS. 3A and 3B show an exemplary embodiment for a model-based target OPC method according to the prior art. A substrate 100, for example, a silicon substrate, on which a photoresist structure 60 is formed is to be seen in FIG. 3A. This photoresist structure 60 is produced with the aid of a mask having a mask layout 20′ shown in FIG. 3B.

The photoresist structure 60 defines interconnect structures 110 in accordance with which interconnects are produced in subsequent process steps, for example by etching or by vapor deposition processes using the photoresist structure 60. The interconnect structures 110 thus image a metallization level, a gate contact connection and a wiring structure for one or more electronic components which are monolithically integrated in the silicon substrate 100.

Also to be seen in FIG. 3A are diffusion zones 120 which have been produced in the silicon substrate 100 in preceding production steps. The interconnect structures 110 run partially over the diffusion zones 120 and partially outside the diffusion zones 120. The diffusion zones 120 belong to active elements—for example field effect transistors—which are monolithically integrated in the silicon substrate 100.

The diffusion zones 120 can therefore also be denoted as “active” zones; the remaining zones of silicon substrate 100, which are situated outside these active zones, are denoted below as “passive” zones of silicon substrate 100. Passive zones are used, for example, for providing the active elements or as landing pads (contact hole landing points).

Those interconnect structures which are situated over the active zones of the silicon substrate 100, and therefore over the diffusion zones 120, and make contact therewith are denoted below as active structures 130. The remaining interconnect structures are subsequently known as inactive or passive structures 140 in what follows.

The mask layout 20′ therefore has “active” layout areas 130′ with the active structures 130, and “passive” layout areas 140′ with the inactive structures 140.

Also to be seen in FIG. 3A is a line break 160 which is to be ascribed to the fact that the permissible process window has been left during exposure of the photoresist structure 60. A further reason for the line break 160 can also consist of the fact that SRAF structures (optically non-resolvable auxiliary structures) have been suitably placed in the region of the line break 160; this will be examined in more detail in conjunction with FIG. 3B.

Visible in FIG. 3B in detail in the mask layout 20′ with which the photoresist structure 60 in accordance with FIG. 3A was produced. The mask layout 20′ has been optimized with the target OPC method according to the prior art.

In addition to the interconnect structures 100, FIG. 3A shows optically non-resolvable auxiliary structures 170 and SRAF (Sub Resolution Assist Feature) structures. These SRAF structures 170 serve the purpose of improving the imaging behavior of the mask layout 20′ and of avoiding aberrations. The SRAF structures 170 are added to the interconnect structures 110 in the course of the target OPC method.

In order to clearly display the position of the SRAF structures 170 relative to the interconnect structures 110 and to the diffusion zones 120, FIG. 3B also further depicts the diffusion zones 120 of the silicon substrate 100; however, these do not form a constituent of the mask layout 20′ but are depicted merely as “reference objects”.

It is to be seen in FIG. 3B that, in the course of the OPC method, in addition to the interconnect structure 110, no SRAF structures 170 to which the line break 160 can at least also be ascribed has being arranged in the region of the line break 160.

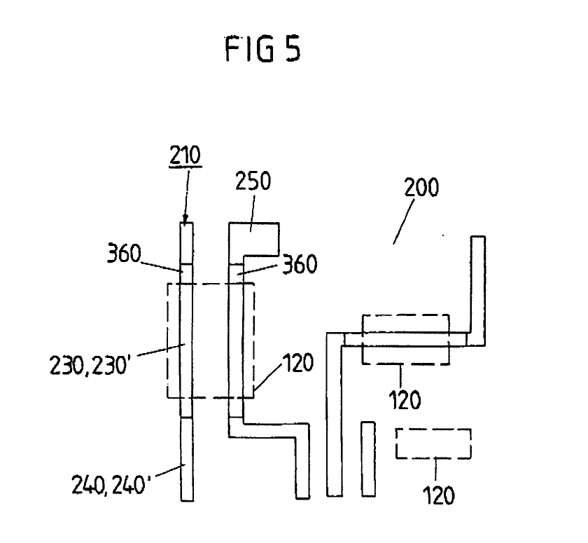

FIGS. 4A and 4B show a further exemplary embodiment for a model-based target OPC method according to the prior art. Visible in FIG. 4A is a line break 180 which is likewise to be ascribed to poor placing of the SRAF structures 170 (compare FIG. 4B).

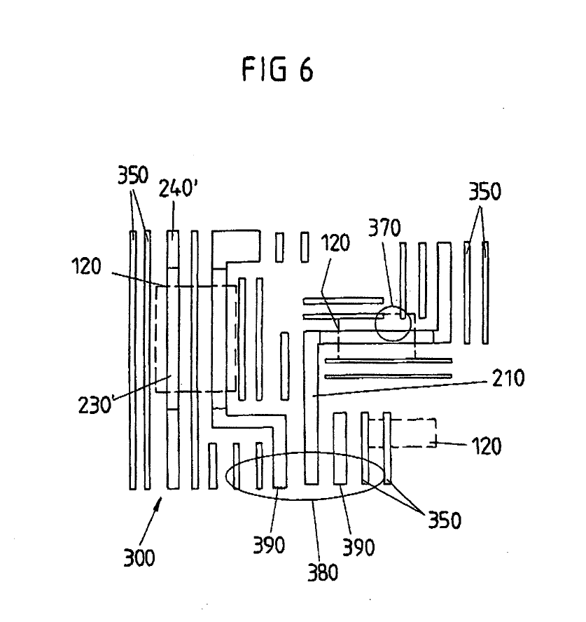

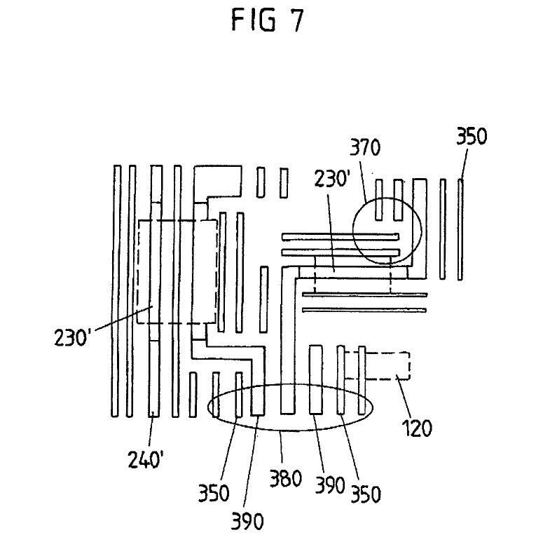

The method according to the invention will now be explained with the aid of a first exemplary embodiment in conjunction with FIGS. 5 and 6.

Visible in FIG. 5 is a provisional auxiliary mask layout 200 which defines metallization structures or interconnect structures 210; the interconnect structures 210 are prescribed by an electrical circuit diagram.

The provisional auxiliary mask layout 200 has active layout areas 230′ and inactive layout areas 240′. As already explained above, the active layout areas 230′ are understood here to be those layout areas of the provisional auxiliary mask layout 200 which are arranged over the active zones of the electric circuit. Active zones are formed, for example, by the diffusion zones of transistors with which contact is made by the active layout areas 230′ of the auxiliary mask layout 200.

As above, inactive layout areas 240′ are understood to be those layout areas which are arranged outside active zones and therefore essentially form connections between the active layout areas 230′ or to external landing pads (or contact hole landing points) 250.

Before carrying out an OPC method, the provisional auxiliary mask layout 200 is subdivided in a first preparatory step into the active layout areas 230′ and into the passive or inactive layout areas 240′ SO that these can be treated differently.

In order to define which layout areas of the preliminary auxiliary mask layout 200 are active and which are the inactive layout areas, the provisional auxiliary mask layout 200 is laid over the mask layout of the prearranged masks—that is to say over the mask layout of those masks which are processed in front of the mask with the mask layout 200 in accordance with FIG. 6. The mask layouts of various mask levels can be laid one on top of the other manually, or preferably, with the aid of an electronic data processing system. The areas in which interconnect structures are situated over diffusion zones can be detected by laying the masks one on top of the other: these zones are regarded below as the active layout areas 230′.

Those layout areas of the provisional auxiliary mask layout 200 which are situated over active zones (transistor zones, in particular diffusion zones or gate areas of transistors) are therefore identified as active layout areas 230′; the remaining layout areas are identified as inactive layout areas 240′.

The provisional auxiliary mask layout 200 is then used in the course of an OPC method to form a final mask layout 300; FIG. 6 shows in this case the mask layout after optically non-resolvable SRAF auxiliary structures have been added to the mask layout in the course of the OPC method. The structure segmentation which normally occurs in the course of an OPC method and is to be seen in FIG. 3B is not illustrated in FIG. 6 for reasons of clarity.

When carrying out the OPC method, the active layout areas 230′ and the passive layout areas 240′ are treated differently—by contrast with the OPC method of the prior art—since the active layout areas and the passive layout areas are subject to a different tolerance requirement. In concrete terms, layout areas 230′ with the active structures 230 are subjected to a target OPC method (or a target OPC variant), whereas the layout areas 240′ with the passive structures 240 are optimized using a defocus OPC method (or defocus OPC variant).

In the course of the OPC method, optically non-resolvable SRAF auxiliary structures 350 are optically added to the interconnect structures 210. The purpose of these SRAF structures is to improve the imaging behavior of the mask layout. Alternatively, the SRAF structures can also be added in a rule-based fashion before carrying out the OPC method; in such a case, a modified auxiliary mask layout is firstly formed from the auxiliary mask layout 200 and the OPC method is carried out using said modified auxiliary mask layout.

It is, however, possible to form in the boundary areas between the active layout areas 230′ and the inactive layout areas 240′ buffer zones 360 which are optionally treated like the active layout areas 230′, like the passive layout areas 240′ or in accordance with a dedicated optimization method. The buffer zones 360 serve to take account of, and as far as possible to compensate, overlay fluctuations or the offsetting of different lithography levels from one another.

FIGS. 6-9 illustrate the different procedures for placing the SRAFs and for treating landing pads in the course of the OPC method. For reasons of clarity, the mask layouts illustrated in FIGS. 6 to 9 are represented without the structural segmentation normally occurring in accordance with an OPC method—as shown in FIG. 3B, for example.

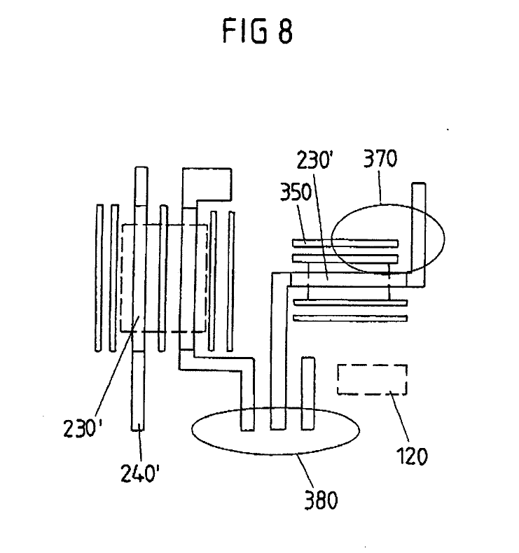

As may be seen from figure. 6, it is possible in the case of conventional placing of the optically non-resolvable auxiliary structures 350 to detect areas in which the optically non-resolvable auxiliary structures (SRAFs) 350 are not arranged optimally. For example, optically non-resolvable auxiliary structures 350 are set in a non-parallel fashion along the gate (active structure) in area 370, it thereby being possible for aberrations to occur in the case of the CD-critical active structure. The wiring structure (passive structure) located to the right above the gate is, by contrast, erroneously optimally supported by SRAFs 350. The “gate first approach” described further below in conjunction with FIG. 7 eliminates this potential defect.

Because of the excessively small distance between the wiring interconnects, no SRAF structures 350 are arranged in another area 380 of FIG. 6. In the OPC step for the structures of the inactive zones, corrections are undertaken in this area 380 in accordance with the defocus OPC (or another process window OPC variant).

The placing of the optically non-resolvable auxiliary structures 350 is undertaken in another way in accordance with a second exemplary embodiment of the method according to the invention. This is shown in accordance with FIG. 7.

It is to be seen that in the exemplary embodiment in accordance with FIG. 7 the optically non-resolvable auxiliary structures 350 are firstly arranged in the region of the active layout areas 230′, and are arranged in the region of the inactive layout areas 240′ only subsequently. This ensures that no defective arrangement for the optically non-resolvable auxiliary structures 350 can arise in the region of the particularly critical active layout areas 230′. By way of example, the problem of defective SRAF placement in area 370 (compare FIG. 6) is eliminated in this way.

Placing the optically non-resolvable auxiliary structures 350 in the region of the active layout areas 230′ can also be denoted as “gate first replacement”, since the optically active areas 230′ are formed by the gate regions of transistors.

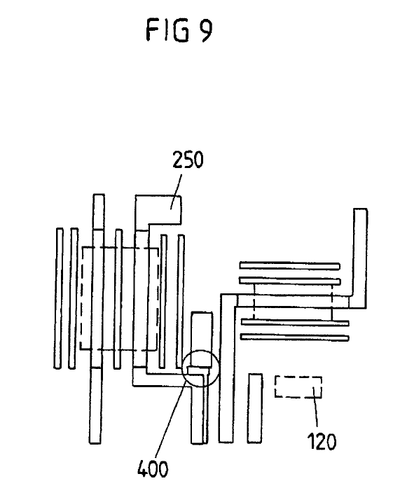

In a third exemplary embodiment of the method, the SRAF auxiliary structures 350 are arranged exclusively in the region of the active layout areas 230′ (compare FIGS. 8 and 9). No SRAF auxiliary structures are placed in the remaining layout areas 240′ (gate-only placement as third exemplary embodiment).

It is to be seen in FIG. 9 that despite the optimization of the mask layout it is possible in accordance with the OPC step for areas 400 to occur in which the inactive layout areas 240′ make contact with the active layout areas 230′. These problems can occur in isolated fashion since—as stated above—the inactive layout areas 240′ are processed with a defocus OPC method such that a certain widening of lines and/or corners results. Such contact areas must be detected, if appropriate in the course of aftertreatment, for example automatic or manual aftertreatment, and repaired (fourth exemplary embodiment).

It is also to be seen in FIG. 9 that the landing pads 250 are preferably likewise subjected to separate treatment (fifth exemplary embodiment), since it is generally impossible to use conventional self-aligned contacts for landing pads, this being so because landing pads regularly have particular overlay requirements owing to the fact that on the one hand landing pads are not allowed to become too small in order to maintain possible contact, and on the other hand they are not allowed to become too large so as to avoid short circuits (bridging) with adjacent wiring structures. Consequently, a target OPC method is generally to be preferred for landing pads, instead of a defocus OPC method.

Just like the active layout areas, landing pads can likewise be detected from mask layouts being laid one on top of the other; alternatively, the landing pads can also be detected manually or with the aid of a data processing system by using their typical geometric dimensions or by using the specifications of the electric circuit.

### List of Reference Symbols

10 Mask
20 Mask layout
20′ Modified or final mask layout
25 Photoresist structure
30 Wafer
40 Light beam
50 focusing lens
60 Resulting photoresist structure
70 OPC Curve
71 Insulated lines
72 Semi-dense structures
73 Very dense structures
100 Silicon substrate
110 Interconnect structures
120 Diffusion zone
130 Active structures
130′ active layout areas
140 Active and passive structures
140′ Passive layout areas
160 Line break
170 Optically non-resolvable SRAF auxiliary structures
180 Line break
200 Provisional auxiliary mask layout
210 Interconnect structures
230 Active structures
230′ Active layout areas
240 Passive structures
240′ Passive layout areas
250 Landing pads
300 Final mask layout
350 SRAF auxiliary structures
360 Buffer zone
370 Defect area
380 Defect area
390 External interconnect
400 Contact area

1. A method for producing for a mask a mask layout which avoids aberrations, in which a provisional auxiliary mask layout produced in accordance with a prescribed electrical circuit diagram is converted into the mask layout with the aid of an Optical Proximity Correction (OPC) method, wherein at least two different OPC variants are used in the course of the OPC method, and wherein the method comprises:
subdividing the original auxiliary mask layout into at least two layout areas; and
processing each of the layout areas in accordance with one of the at least two OPC variants.

2. The method according to claim 1, wherein the OPC method comprises a process window OPC variant, in particular a defocus OPC variant and/or a target OPC variant.

3. Method according to claim 1, wherein the provisional auxiliary mask layout is subdivided into at least one layout area with at least one active structure, and into at least one layout area with at least one passive structure.

4. The method according to claim 3, wherein the at least one layout area with the at least one active structure is subjected to the target OPC variant, and the at least one layout area with the at least one inactive structure is subjected to a process window OPC variant, in particular a defocus OPC variant.

5. The method according to claim 4, wherein gate structures are treated as the active structures.

6. The method according to claim 1, wherein a model-based OPC variant is carried out as process window OPC variant, in particular as defocus OPC variant.

7. The method according to claim 1, wherein a rule-based OPC variant is carried out as process window OPC variant, in particular as defocus OPC variant.

8. The method according to claim 1, wherein a model-based OPC variant is carried out as target OPC variant.

9. The method according to claim 1, wherein a rule-based OPC variant is carried out as target OPC variant.

10. The method according claim 1, wherein
a modified auxiliary mask layout is firstly formed before carrying out the OPC method with the provisional auxiliary mask layout
by supplementing the mask structures of the provisional auxiliary mask layout in a first modification step with the formation of modified mask structures in accordance with prescribed placing rules by means of optically non-resolvable auxiliary structures with the formation of the modified auxiliary mask layout, and
the mask layout is produced with the aid of the OPC method by using the modified auxiliary mask layout.

11. The method according to claim 10, wherein the layout areas with the optically non-resolvable auxiliary structures are subjected to a different OPC variant from the layout areas without the optically non-resolvable auxiliary structures.

12. The method according to claim 1, wherein firstly the layout areas with the active structures, in particular firstly the layout areas with the gate structures, are supplemented by means of optically non-resolvable auxiliary structures.

13. The method according to claim 1, wherein only the layout areas with the active structures, in particular only the layout areas with the gate structures, are supplemented by means of optically non-resolvable auxiliary structures.

14. The method according to claim 1, wherein it is ensured when producing the mask layout that interconnects are situated only over those active zones for which the aim is to make a contact.

15. The method according to claim 14, wherein it is ensured when producing the mask layout that interconnects are situated only over those gate structures for which the aim is to make contact with the gate.

16. The method according to claim 1, wherein it is ensured when producing the mask layout that wiring structures are treated such that they lie outside active zones.

17. The method according to claim 1, wherein when producing the mask layout pad structures and remaining wiring structures are treated differently.

18. The method according to claim 17, wherein when producing the mask layout use is made of a target OPC variant for pad structures.

19. The method according to claim 1, wherein the method is carried out on at least one of non-gate levels, RX areas, and metallization levels of the mask layout.

20. The method according to claim 1, wherein CD-critical and CD-non-critical structures are subject to different OPC variants.

21. The method according to claim 1, wherein the method is used for DRAM mask layouts.

22. The method according to claim 21, wherein cell field structures and cell field edge structures are processed with different OPC variants.

23. The method according to claim 1, wherein electrically necessary mask structures and unnecessary dummy structures are treated differently.

24. A method for producing a mask including a final mask layout for producing a prescribed electrical circuit, wherein the method comprises:
generating a provisional mask layout in accordance with the prescribed electrical circuit,
subdividing the provisional mask layout into at a first layout area and a second layout area;
processing each of the first and second layout areas in accordance with one of at least two Optical Proximity Correction (OPC) variants to form the final mask layout, wherein the first layout area is processed in accordance with a first OPC variant and the second layout area is processed in accordance with a second OPC variant.
